(19) United States
(12) Patent Application Publication
(10) Pub. No.: US 2025/0370358 A1
(43) Pub. Date: Dec. 4, 2025

(54) CONTAMINATION CONTROL

(71) Applicant: ASML Netherlands B.V., Veldhoven (NL)

(72) Inventors: Manis CHAUDHURI, Eindhoven (NL); Christian Gerardus Norbertus Hendricus Marie CLOIN, Eindhoven (NL); Andrei Mikhailovich YAKUNIN, Veldhoven (NL)

(73) Assignee: ASML Netherlands B.V., Veldhoven (NL)

(21) Appl. No.: 19/125,621

(22) PCT Filed: Oct. 11, 2023
(86) PCT No.: PCT/EP2023/078200

§ 371 Date: Apr. 29, 2025

(30) Foreign Application Priority Data
Nov. 8, 2022 (EP) 22206094.9

(51) Int. Cl. G03F 7/00

(52) U.S. Cl. CPC G03F 7/70925; G03F 7/70033; G03F 7/70808; G03F 7/70933; G03F 7/70991

(57) ABSTRACT

A lithographic patterning device contamination control assembly comprising a support structure configured to support a patterning device floating with respect to ground, a masking apparatus configured to selectively mask the lithographic patterning device, the masking apparatus being connected to ground, a gas supply and an ionizer, the gas supply being configured to supply gas to the ionizer, and the ionizer being configured to convert the gas to a quasi-neutral plasma which is located in a region between the masking apparatus and the lithographic patterning device.

### CROSS-REFERENCE TO RELATED APPLICATIONS

This application claims priority of EP application 22206094.9 which was filed on 8th Nov. 2022, and which is incorporated herein in its entirety by reference.

### FIELD

The present invention relates to contamination control in a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a deep ultraviolet (DUV) wavelength of 193 nm.

In a conventional (DUV) lithographic apparatus, a pellicle is attached to the patterning device. The pellicle is a membrane which is spatially separated from the patterning device. A contamination particle which is incident upon the pellicle will be out of focus when projected by the lithographic apparatus onto a substrate. As a result, the contamination particle does not introduce a defect into a pattern projected by the lithographic apparatus from the patterning device onto the substrate.

A pellicle may also be used in an EUV lithographic apparatus. However, EUV radiation is absorbed by the pellicle, and this reduces the intensity of EUV radiation which may be used to expose a substrate. This in turn reduces the throughput of the lithographic apparatus.

It may be desirable to provide an apparatus that overcomes or mitigates one or more problems associated with the prior art.

### SUMMARY

According to a first aspect of the present invention, there is provided a lithographic patterning device contamination control assembly comprising a support structure configured to support a patterning device the patterning device floating with respect to ground, a masking apparatus configured to selectively mask the lithographic patterning device, the masking apparatus being connected to ground, a gas supply and an ionizer, the gas supply being configured to supply gas to the ionizer, and the ionizer being configured to convert the gas to a quasi-neutral plasma which is located in a region between the masking apparatus and the lithographic patterning device.

Advantageously, there is substantially no electric field within the quasi-neutral plasma and thus charged contamination particles are not accelerated towards the patterning device. Instead the charged contamination particles may remain within the quasi-neutral plasma.

The assembly may further comprise a gas removal system configured to remove gas from a housing within which the support structure and the masking apparatus are located.

The term “gas removal” may include plasma removal.

The gas removal system may be located on an opposite side of an EUV radiation exposure zone from the gas supply system.

The masking apparatus may comprise a blade.

The gas supply system may be located between the blade and the support structure.

The ionizer may be located between the blade and the support structure.

The ionizer may be located on the same side of an EUV radiation exposure zone as the gas supply system.

The ionizer may be located beneath the blade.

The ionizer may comprise a filament, an electron beam source, or an RF system.

The lithographic patterning device contamination control may further comprise one or more additional ionizers.

According to a second aspect of the invention there is provided a lithographic apparatus comprising the lithographic patterning device contamination control assembly of the first aspect.

According to a third aspect of the invention there is provided a method of controlling contamination of a lithographic patterning device, the method comprising providing a lithographic patterning device which is not connected to ground, providing a masking apparatus which is connected to ground, directing EUV radiation onto the lithographic patterning device at an exposure zone which is defined by the masking apparatus, and providing a quasi-neutral plasma to a region between the masking apparatus and the lithographic patterning device gas.

The method may further comprise removing gas from the region between the masking apparatus and the lithographic patterning device.

The masking apparatus may comprise at least one blade. The quasi-neutral plasma is located between the at least one blade and the patterning device.

The masking apparatus may comprise a pair of blades. The quasi-neutral plasma may be located between each blade of the pair of blades and the patterning device.

The quasi-neutral plasma may be located next to an exposure zone of the lithographic apparatus.

The quasi-neutral plasma may be at least partially generated by an ionizer which is located between the masking apparatus and the patterning device.

The quasi-neutral plasma may be at least partially generated by an ionizer which is not located between the masking apparatus and the patterning device, and wherein gas flow within an environment in which the patterning device is provided moves the quasi-neutral plasma to between the masking apparatus and the patterning device.

The quasi-neutral plasma may be generated by a plurality of ionizers.

There may be a continuous flow of gas and quasi-neutral plasma through an environment in which the patterning device is provided.

Features of different aspects of the invention may be combined together.

### BRIEF DESCRIPTION OF THE DRAWINGS

Embodiments of the invention will now be described, by way of example only, with reference to the accompanying schematic drawings, in which:

FIG. 1 schematically depicts a lithographic system which includes a contamination control assembly according to an embodiment of the invention;

FIG. 2 schematically depicts the contamination control assembly in more detail; and;

FIG. 3 schematically depicts operation of part of the contamination control assembly.

### DETAILED DESCRIPTION

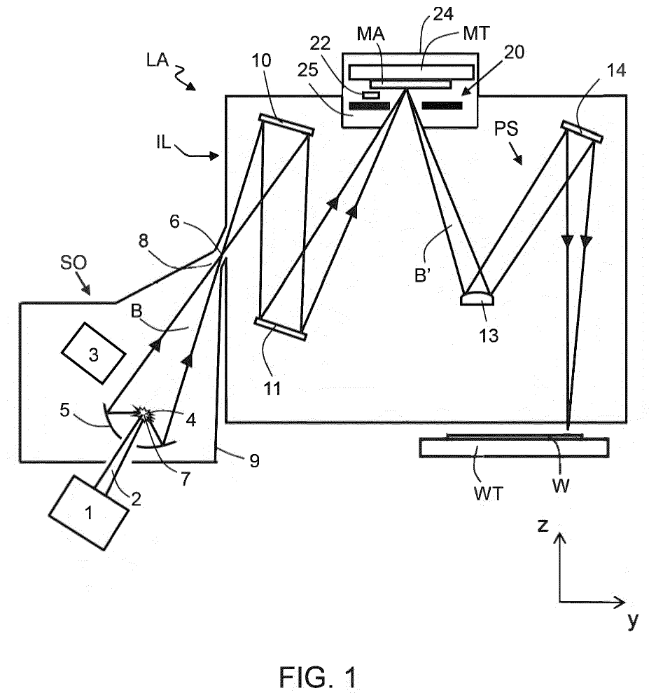

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 1, the projection system PS may include a different number of mirrors (e.g., six or eight mirrors).

The support structure MT may comprise a clamp that is used to hold the patterning device MA. The clamp may be an electrostatic clamp that is electrically driven. There may be a dielectric layer between the clamp and the patterning device MA. The patterning device MA is floating with respect to electrical ground. At least part of the support structure MT may be at electrical ground.

The patterning device MA and other elements may be provided within a housing 24. An interior defined by the housing may be referred to as a patterning device environment 25. The housing 24 may be substantially closed, apart from an opening at a bottom end of the housing. A masking apparatus 20 which comprises a pair of reticle masking blades is provided in the patterning device environment 25. The masking apparatus 20 is used to selectively mask areas of the patterning device MA, such that only a desired portion of the patterning device receives EUV radiation at any given time. During a scanning exposure, the patterning device MA and support structure MT move in the y-direction, and the substrate W and substrate table WT move in the opposite y-direction (and vice-versa). In this way, a band of EUV radiation passes over the patterning device MA and passes over an exposure field on the substrate W.

An ionizer 22 is provided in the patterning device environment 25. The ionizer 22 in FIG. 1 is between a blade of the reticle masking blade system 20 and the patterning device MA. However, the ionizer may be provided at a different location within the patterning device environment 25. The ionizer is configured to induce a quasi-neutral plasma in a region between the reticle masking blade system 20 and the patterning device MA. This quasi-neutral plasma reduces the likelihood of contamination particles being incident upon the patterning device MA, as explained further below.

A relative vacuum, i.e. a small amount of gas (e.g. hydrogen) at a pressure well below atmospheric pressure, may be provided in the radiation source SO, in the illumination system IL, and/or in the projection system PS. The same is also the case for the patterning device environment 25. That is, gas at a pressure below atmospheric pressure is present in the patterning device environment 25. The gas may for example be hydrogen.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal 10 points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

Although FIG. 1 depicts the radiation source SO as a laser produced plasma (LPP) source, any suitable source such as a discharge produced plasma (DPP) source or a free electron laser (FEL) may be used to generate EUV radiation.

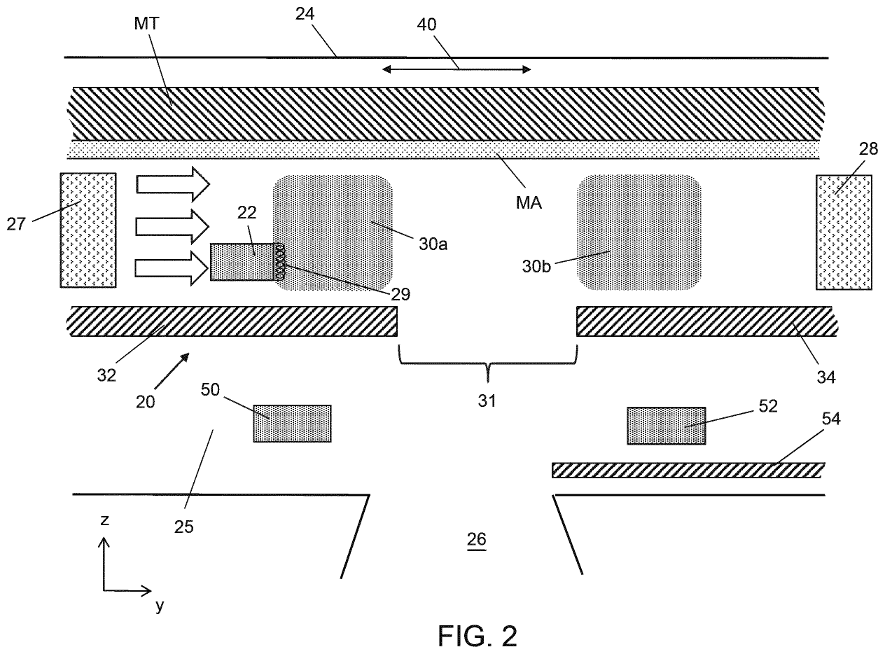

FIG. 2 schematically depicts part of the lithographic apparatus LA in more detail. Specifically, FIG. 2 schematically depicts the patterning device MA, support structure MT, masking apparatus 20, ionizer 22 and other elements which are provided in the housing 24. An opening 26 is provided at a lowermost end of the housing 24. The EUV radiation beam enters the housing 24 (and enters the patterning device environment 25) through this opening 26, is reflected from the patterning device MA and then exits through the same opening 26. The masking apparatus 20 defines an exposure zone 31 through which the EUV radiation passes.

A gas supply system 27 is provided in the housing 24. The gas supply system 27 comprises one or more gas inlets which are configured to deliver gas to the patterning device environment 25. The gas may be provided at a pressure which is below atmospheric pressure. The gas may for example be hydrogen gas. The gas supply system 27 may be located between a masking blade 32 of the masking apparatus 20 and the patterning device MA.

A gas removal system 28 is provided in the housing 24. In the depicted embodiment the gas removal system 28 is at an opposite side of the exposure zone 31 from the gas supply system 27 (although the gas removal system 28 may be provided at a different location). The gas removal system 28 comprises one or more outlets which are configured to receive quasi-neutral plasma from the patterning device environment 25. The gas removal system 28 may further comprise a pump (not depicted) configured to pump quasi-neutral plasma. The gas removal system 28 removes gas and quasi-neutral plasma from the from the patterning device environment 25. In addition, the gas removal system 28 removes contamination from the patterning device environment (as explained further below). The gas removal system 28 may be located between a masking blade 34 of the masking apparatus 20 and the patterning device MA.

FIG. 2 is schematic and is not intended to show accurately the sizes or spatial configurations of elements in the patterning device environment 25.

As depicted by arrows, the gas supply system 27 and gas removal system 28 provide a flow of gas across the patterning device environment 25. In particular, there is a flow of gas through a space between the masking apparatus 20 and the patterning device MA. The flow of gas may be generally in single direction (e.g. the scanning direction of the lithographic apparatus). However, the flow of gas may be more complex, and may include flow in several different directions. There may be a continuous flow of gas and quasi-neutral plasma through the patterning device environment 31.

Gas may be delivered via one or more inlets (not depicted) at the opening 26 or adjacent to the opening 26. Gas flow may be from the opening 26 towards the support structure MT. This gas flow may beneficially reduce the likelihood of contamination particles being incident upon reflectors 10, 11, 13, 14 of the lithographic apparatus (see FIG. 1). The gas supply system 27 may be located outside of the housing 24, for example in the opening 26 which connects to the housing.

In the depicted embodiment, the ionizer 22 is located downstream of the gas supply system 27. The ionizer 22 may for example comprise a filament 29. A voltage is applied to the filament, and the voltage causes the hydrogen gas to ionise to form a quasi-neutral plasma as the gas flows over the filament. The flow of gas over the ionizer 22 (in this case filament 29) induces a quasi-neutral plasma 30 between the patterning device MA and a blade 32 of the masking apparatus 20.

In other embodiments, the ionizer need not necessarily be located downstream of the gas supply system. Gas within the patterning device environment 25 may move in a variety of different directions, and as a result of this movement may come into contact with ionizer. In general, it is desirable for the gas to reach the ionizer in order that the quasi-neutral plasma can be generated.

In an embodiment, the filament 29 of the ionizer 22 is provided with sufficient energy to remove electrons from the gas which flows over it. For example, the ionization energy for a hydrogen atom is 13.6 eV, and the ionization energy for a H₂ molecule is 15.4 eV. The filament 29 may be provided with a current of 0.1 A at a voltage of 5V. Other currents and voltages may be used. The filament may be powered using a 0.1-5 W power supply. Electrons released by the filament 29 may have an energy which is greater than the ionisation energy of the gas flowing over the filament. The ionizer 22 may comprise a plurality of filaments.

As depicted, the masking apparatus 20 may comprise two blades 32, 34 which are separated from each other in a scanning-direction of the lithographic apparatus. The scanning direction may be referred to as the Y-direction. As schematically depicted, a first quasi-neutral plasma 30a may be formed between a first masking blade 32 and the patterning device MA, and a second quasi-neutral plasma 30b may be formed between a second masking blade 34 and the patterning device MA. The quasi-neutral plasma 30a,b may be located next to the exposure zone 31 (as depicted).

In some embodiments, quasi-neutral plasma may be provided only to one side of the exposure zone 31 (or primarily to one side of the exposure zone).

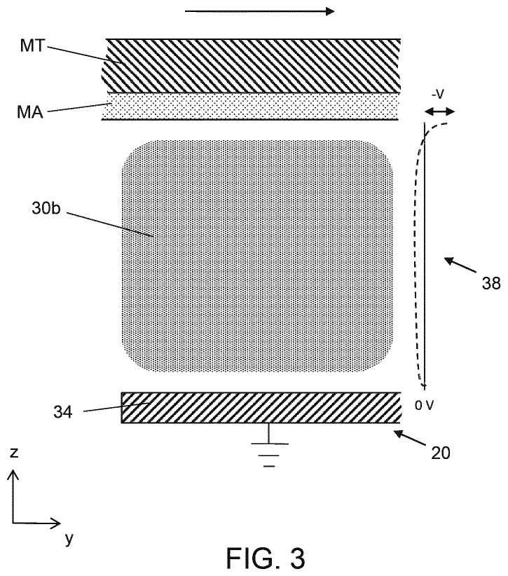

FIG. 3 schematically depicts part of the patterning device MA and support structure MT, and part of the second blade 34 of the masking apparatus 20. As schematically depicted, the quasi-neutral plasma 30b is between the patterning device MA and second blade 34. To the right hand side of FIG. 3, a voltage between the second blade 34 and the patterning device MA is schematically indicated by a dashed line in a schematic graph 38.

As indicated, the masking apparatus 20, including the second blade 34, is connected to ground. At least part of the support structure MT is connected to ground. However, the patterning device MA is not connected to ground. Instead the patterning device MA is floating with respect to ground. When the EUV radiation beam B (see FIG. 1) is incident upon the patterning device MA during a lithographic exposure, it causes electrons to be emitted from the surface of the patterning device MA. As a result, the surface of the patterning device MA becomes positively charged. As schematically indicated by the double-headed arrow 40 in FIG. 2, the patterning device MA and support structure MT move backwards and forwards in the scanning-direction (the Y-direction).

In FIG. 3, an area of the patterning device MA which became positively charged when it passed through the EUV radiation beam B (not depicted), then moved such that it is directly above the quasi-neutral plasma 30b (the movement is indicated by the arrow). In this example the patterning device MA moved in the positive Y-direction. However, in other examples the patterning device MA moves in the negative Y-direction and will be above the first quasi-neutral plasma 30a after passing through the EUV radiation beam.

Because the patterning device MA is positively charged, it attracts electrons from the quasi-neutral plasma 30b. As a result, the surface of the patterning device MA becomes negatively charged. This is schematically indicated by the voltage graph 38 having a negative voltage at the surface of the patterning device MA.

Because the second blade 34 of the masking apparatus 20 is connected to ground, the voltage at the second blade is zero. The quasi-neutral plasma has donated some electrons to the surface of the patterning device MA, and as a result is slightly positively charged. This is represented as a slight positive voltage on the graph 38.

The quasi-neutral plasma comprises generally equal amounts of electrons and positive ions. As a result, there is no significant electric field within the quasi-neutral plasma. This is schematically indicated by the voltage graph 38, which shows that there is no significant change of voltage within the quasi-neutral plasma 30b (since the voltage is substantially constant it follows that there is no significant electric field within the quasi-neutral plasma).

Charged contamination particles which are within the quasi-neutral plasma do not experience a significant electric field. As a result, the charged contamination particles are not accelerated by an electric field towards the patterning device MA. If the quasi-neutral plasma 30b were not present, then the patterning device MA would be strongly positively charged due to the effect of the EUV radiation beam on the patterning device MA. Consequently, a substantial electric field would exist between the patterning device MA and the second blade 34 of the masking apparatus 20. This substantial electric field would accelerate negatively charged contamination particles towards the patterning device MA such that the contamination particles would be likely to be incident upon the patterning device MA. This would cause defects in the pattern projected by the lithographic apparatus onto a substrate W. The quasi-neutral plasma avoids this problem because it provides an environment in which charged contamination particles are not accelerated towards the patterning device MA. Thus, contamination of the patterning device MA is reduced. This reduction of the contamination of the patterning device MA is achieved without the requirement for a pellicle, and thus without the corresponding reduction of EUV radiation intensity which is associated with the use of a pellicle.

As may be seen from the voltage graph 38 in FIG. 3, an electric field exists in a region immediately adjacent to the patterning device MA. This region may be referred to as a sheath region. The surface of the patterning device MA is negatively charged, as explained above. As a result, in the sheath region an electric field exists which repels negatively charged particles towards the quasi-neutral plasma. This is advantageous because the effect of EUV radiation in the exposure zone 31 is such that contamination particles are negatively charged. These negatively charged contamination particles are deflected away from the patterning device MA by the electric field. The negatively charged contamination particles enter the quasi-neutral plasma where they no longer experience any electrical force. The negatively charged contamination particles are then removed from the patterning device environment 25 as explained below.

As described further above in connection with FIG. 2, the gas supply system 27 and the gas removal system 28 provide a flow of gas (and a flow of quasi-neutral plasma) across the patterning device environment 25. This flow of gas removes charged contamination particles from the patterning device environment 25. Charged contamination particles which are within the quasi-neutral plasma 30a,b travel out through the gas removal system 28. Charged particles which are in the sheath area between the quasi-neutral plasma 30a,b and the patterning device MA may also be removed by the flow of gas (the flow of gas may divert charged particles away from being incident upon the patterning device MA).

A sheath area may also exist between the quasi-neutral plasma 30a,b and the blades 32, 34 of the masking apparatus 20. In this case, because the masking apparatus 20 is connected to ground, there is no acceleration of charged particles towards the masking apparatus. Again, the flow of gas from the gas supply system 27 to the gas removal system 28 may carry charged contamination particles out of the patterning device environment 25, instead of the charged contamination particles being incident upon the blades 32, 34.

The quasi-neutral plasma 30a,b is depicted in FIG. 2 as being generally located above inner ends of the first and second blades 32, 34 of the masking apparatus 20. The quasi-neutral plasma may be primarily located in these areas. However, the quasi-neutral plasma may extend into other areas.

The patterning device environment 25 is dynamic in the sense that the patterning device MA is moving in the positive and negative Y-directions, and thus experiencing the charging effect of the EUV radiation, whilst at the same time the gas supply system 27 is delivering gas to the ionizer 22 and thus replenishing the quasi-neutral plasma. The gas removal system 28 is removing the quasi-neutral plasma and contamination particles from the patterning device environment whilst new gas is being delivered by the gas supply system 27, thereby establishing a flow of gas.

The flow of gas may be such that the ionizer 22 need not necessarily be located between a blade 32 of the masking apparatus 20 and the patterning device MA. Instead, the ionizer may be provided in a different location in the patterning device environment 25, and may nevertheless still provide a quasi-neutral plasma in a volume between the masking apparatus 20 and the patterning device MA.

In an embodiment, the ionizer 50 may be located beneath a first blade 32 of the masking apparatus 20 but still within the patterning device environment 25. In another embodiment, the ionizer 52 may be located beneath the second blade 34 of the masking apparatus 20 but still within the patterning device environment 25. In this case, the ionizer 52 may be located above a beam attenuator 54 which is configured to move into partial intersection with the EUV radiation beam to reduce intensity of the EUV radiation beam when this is desired.

As explained further above, the ionizer may comprise a filament provided with a combination of current and voltage that is able to separate electrons from a gas flowing over the filament.

In embodiment, the ionizer 22, 50, 52 may comprise an electron beam source. Where this is the case, the electrons provided from the electron beam source may have an energy which is greater than the ionisation energy of a gas in the patterning device environment 25. For example, the electrons may have an energy which is greater than 30.6 eV when the gas is hydrogen.

In an embodiment, the ionizer 22, 50, 52 may be an RF system. The RF system may be configured to modulate at a frequency of around 13.56 MHz. This frequency is known to be absorbed efficiently by electrons, and this may cause electrons to be liberated from molecules to form the quasi-neutral plasma. The amplitude of the RF modulation may for example be a few volts (measured peak-to-peak). The RF system may for example comprise capacitively coupled plates or inductively coupled elements. The capacitively coupled plates may be circular, or may have some other shape.

The ionizer may be an electron cyclotron resonance (ECR) plasma source.

More than one ionizer may be provided.

In this document, references to gas removal may be interpreted as encompassing removal of quasi-neutral plasma.

In this document, references to ground may be interpreted as referring to electrical ground (which may alternatively be referred to as electrical earth or merely earth).

A method according to an embodiment of the invention may be performed by a computing device. The device may comprise a central processing unit (“CPU”) to which is connected a memory. The method described herein may be implemented in code (software) stored on a memory comprising one or more storage media, and arranged for execution on a processor comprising on or more processing units. The storage media may be integrated into and/or separate from the CPU. The code, which may be referred to as instructions, is configured to be fetched from the memory and executed on the processor to perform operations in line with embodiments discussed herein. Alternatively it is not excluded that some or all of the functionality of the CPU is implemented in dedicated hardware circuitry, or configurable hardware circuitry like an FPGA.

The computing device may comprise an input configured to enable a user to input data into a software program running on the CPU. The input device may comprise a mouse, keyboard, touchscreen, microphone etc. The computing device may further comprises an output device configured to output results of measurements to a user.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-20. (canceled)

21. A lithographic patterning device contamination control assembly comprising:
a support structure configured to support a patterning device, the patterning device floating with respect to ground;
a masking apparatus configured to selectively mask the lithographic patterning device, the masking apparatus being connected to ground;
a gas supply; and
an ionizer,
wherein the gas supply is configured to supply gas to the ionizer, and
wherein the ionizer is configured to convert the gas to a quasi-neutral plasma which is located in a region between the masking apparatus and the lithographic patterning device.

22. The lithographic patterning device contamination control assembly of claim 21, further comprising:
a housing within which the support structure and the masking apparatus are located; and
a gas removal system configured to remove gas from the housing.

23. The lithographic patterning device contamination control assembly of claim 22, wherein the gas removal system is located on an opposite side of an EUV radiation exposure zone from the gas supply.

24. The lithographic patterning device contamination control assembly of claim 21, wherein the masking apparatus comprises a blade.

25. The lithographic patterning device contamination control assembly of claim 24, wherein the gas supply is located between the blade and the support structure.

26. The lithographic patterning device contamination control assembly of claim 24, wherein the ionizer is located between the blade and the support structure.

27. The lithographic patterning device contamination control assembly of claim 26, wherein the ionizer is located on a same side of an EUV radiation exposure zone as the gas supply.

28. The lithographic patterning device contamination control assembly of claim 24, wherein the ionizer is located beneath the blade.

29. The lithographic patterning device contamination control assembly of claim 21, wherein the ionizer comprises a filament, an electron beam source, or an RF system.

30. The lithographic patterning device contamination control assembly of claim 21, further comprising one or more additional ionizers.

31. A lithographic apparatus comprising:
the lithographic patterning device contamination control assembly of claim 21.

32. A method of controlling contamination of a lithographic patterning device, the method comprising:
providing a lithographic patterning device which is not connected to ground;
providing a masking apparatus which is connected to ground;
directing EUV radiation onto the lithographic patterning device at an exposure zone which is defined by the masking apparatus; and
providing a quasi-neutral plasma to a region between the masking apparatus and the lithographic patterning device gas.

33. The method of claim 32, further comprising removing gas from the region between the masking apparatus and the lithographic patterning device.

34. The method of claim 32, wherein:
the masking apparatus comprises at least one blade, and
the quasi-neutral plasma is located between the at least one blade and the patterning device.

35. The method of claim 34, wherein:
the masking apparatus comprises a pair of blades, and
the quasi-neutral plasma is located between each blade of the pair of blades and the patterning device.

36. The method of any claim 32, wherein the quasi-neutral plasma is located next to an exposure zone of the lithographic apparatus.

37. The method of any of claim 32, wherein the quasi-neutral plasma is at least partially generated by an ionizer which is located between the masking apparatus and the patterning device.

38. The method of claim 32, wherein:
the quasi-neutral plasma is at least partially generated by an ionizer which is not located between the masking apparatus and the patterning device, and
gas flow within an environment in which the patterning device is provided moves the quasi-neutral plasma to between the masking apparatus and the patterning device.

39. The method of claim 37, wherein the quasi-neutral plasma is generated by a plurality of ionizers.

40. The method of claim 32, wherein there is a continuous flow of gas and quasi-neutral plasma through an environment in which the patterning device is provided.
